(19) United States
(12) Patent Application Publication
(10) Pub. No.: US 2016/0104860 A1
(43) Pub. Date: Apr. 14, 2016

(54) ORGANIC ELECTROLUMINESCENT DISPLAY DEVICE AND METHOD FOR MANUFACTURING THE SAME

(71) Applicant: Japan Display Inc., Tokyo (JP)

(72) Inventors: Koji Yasukawa, Tokyo (JP); Jun Takagi, Tokyo (JP)

(21) Appl. No.: 14/877,716

(22) Filed: Oct. 7, 2015

(30) Foreign Application Priority Data
Oct. 8, 2014 (JP) 2014-207329

(51) Int. Cl. H01L 51/52; H01L 27/32; H01L 51/56

(52) U.S. Cl. CPC H01L 51/5234; H01L 51/56; H01L 51/5246; H01L 27/3244; H01L 2251/308; H01L 2251/301

(57) ABSTRACT

An organic electroluminescent element is formed to have a transparent electrode as a cathode. An ultraviolet-absorbing layer having a higher ultraviolet absorptivity than the transparent electrode is formed on the transparent electrode. A sealing film is formed on the ultraviolet-absorbing layer by a plasma CVD process.

### CROSS-REFERENCE TO RELATED APPLICATION

The present application claims priority from Japanese application JP2014-207329 filed on Oct. 8, 2014, the content of which is hereby incorporated by reference into this application.

### BACKGROUND OF THE INVENTION

1. Field of the Invention

The present invention relates to an organic electroluminescent display device and a method for manufacturing the organic electroluminescent display device.

2. Description of the Related Art

An organic electroluminescent display device has a sealing structure for isolating an organic electroluminescent (EL) element from the air. The sealing structure is, of course, required to have barrier properties and also required to have transparency for top emission types, which allow emitted light to exit through the top. To meet these requirements for the material, silicon nitride (SiN) is used as sealing films. Many of such silicon nitride films are formed by plasma chemical vapor deposition (CVD) (JP2009-037813A).

In a plasma CVD process, ultraviolet rays are emitted. The top layer electrode of a top-emitting organic EL element is transparent. Thus, the ultraviolet rays, which pass through this electrode, deteriorate or deactivate the light-emitting materials, and consequently reduce the luminescent efficiency.

### SUMMARY OF THE INVENTION

It is an object of the present invention to reduce the effect of ultraviolet rays emitted in a plasma CVD process.

(1) A method for manufacturing an organic electroluminescent display device according to an aspect of the present invention includes the following steps. An organic electroluminescent element is formed to have a transparent electrode as a cathode. An ultraviolet-absorbing layer having a higher ultraviolet absorptivity than the transparent electrode is formed on the transparent electrode. A sealing film is formed on the ultraviolet-absorbing layer by a plasma CVD process. According to this aspect, the ultraviolet-absorbing layer, which absorbs ultraviolet rays, can reduce the effect of the ultraviolet rays emitted in the plasma CVD process on the organic electroluminescent element.

(2) In the method according to the item (1), the sealing film may be formed of a silicon nitride-containing material by using silane gas in the plasma CVD process.

(3) In the method according to the item (1) or (2), both the transparent electrode and the ultraviolet-absorbing layer may be formed of indium zinc oxide, and the ultraviolet-absorbing layer may have a higher percentage of oxygen than the transparent electrode.

(4) In the method according to the item (1) or (2), the transparent electrode may be formed of indium zinc oxide, and the ultraviolet-absorbing layer may be formed of amorphous indium tin oxide.

(5) In the method according to the item (1) or (2), the ultraviolet-absorbing layer may be formed to contain an aromatic compound or a heterocycle compound.

(6) In the method according to any one of the items (1) to (4), the ultraviolet-absorbing layer may be conductive and in close contact with the transparent electrode.

(7) An organic electroluminescent display device according to an aspect of the present invention includes an organic electroluminescent element having a transparent electrode as a cathode, an ultraviolet-absorbing layer on the transparent electrode, and a sealing film on the ultraviolet-absorbing layer. The ultraviolet-absorbing layer has a higher ultraviolet absorptivity than the transparent electrode. The sealing film is made of a silicon nitride-containing material. According to this aspect, the ultraviolet-absorbing layer, which absorbs ultraviolet rays, can reduce the effect of the ultraviolet rays on the organic electroluminescent element.

(8) In the organic electroluminescent display device according to the item (7), the transparent electrode may be formed of indium zinc oxide, and the ultraviolet-absorbing layer may be formed of indium zinc oxide having a higher percentage of oxygen than the transparent electrode.

(9) In the organic electroluminescent display device according to the item (7), the transparent electrode may be formed of indium zinc oxide, and the ultraviolet-absorbing layer may be formed of amorphous indium tin oxide.

(10) In the organic electroluminescent display device according to the item (7), the ultraviolet-absorbing layer may be formed to contain an aromatic compound or a heterocycle compound.

### BRIEF DESCRIPTION OF THE DRAWINGS

FIG. 1 is a diagram showing an organic electroluminescent display device according to an embodiment of the present invention;

FIG. 2 is a table showing the results of an experiment to determine the effect of ultraviolet rays emitted in a plasma CVD process on an organic electroluminescent element;

FIG. 3 is a diagram showing organic electroluminescent elements according to Comparative Examples 1 to 4; and

FIG. 4 is a diagram showing organic electroluminescent elements according to Examples 1 to 3.

### DETAILED DESCRIPTION OF THE INVENTION

An embodiment of the present invention will now be described with reference to the accompanying drawings.

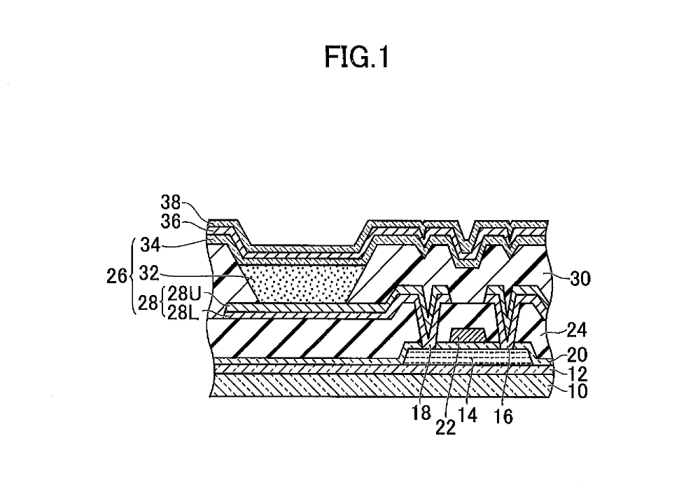

FIG. 1 is a diagram showing an organic electroluminescent display device according to an embodiment of the present invention. The organic electroluminescent display device has a substrate 10 made of, for example, glass. An undercoat 12 is disposed on the substrate 10 and acts as a barrier against impurities from the substrate 10. A semiconductor layer 14 is disposed on the undercoat 12. A source electrode 16 and a drain electrode 18 are disposed on the semiconductor layer 14. A gate insulating film 20 covers the semiconductor layer 14. A gate electrode 22 is disposed on the gate insulating film 20. An interlayer insulating film 24 covers the gate electrode 22. The semiconductor layer 14, the source electrode 16, the drain electrode 18, and the gate electrode 22 constitute a thin film transistor.

The organic electroluminescent display device has an organic electroluminescent element 26. The organic electroluminescent element 26 includes a lower electrode 28 (e.g., an anode). The lower electrode 28 is disposed on the interlayer insulating film 24. The lower electrode 28 includes a lower layer 28L that reflects light and an upper layer 28U that allows light to pass through it. A conductive layer including a portion to be the lower electrode 28 extends through the interlayer insulating film 24 and is electrically coupled to one of the source electrode 16 and the drain electrode 18 on the semiconductor layer 14.

An insulating layer 30 is disposed on the interlayer insulating film 24 and the lower electrode 28. The insulating layer 30 has an opening to part of the lower electrode 28. The insulating layer 30 forms a bank enclosing the part of the lower electrode 28.

The organic electroluminescent element 26 includes an organic layer 32. The organic layer 32 is disposed on the lower electrode 28. The organic layer 32 includes at least a light-emitting layer and may further include at least one of an electron transport layer, a hole transport layer, an electron injection layer, and a hole injection layer. At least one layer constituting the organic layer 32 is made of an organic material.

The organic electroluminescent element 26 has a transparent electrode 34 (e.g., a cathode) as its top layer. The transparent electrode 34 is disposed on the organic layer 32. The transparent electrode 34 is formed to lie on the insulating layer 30 to be the bank.

An ultraviolet-absorbing layer 36 is disposed on the transparent electrode 34. The ultraviolet-absorbing layer 36 has a higher ultraviolet absorptivity than the transparent electrode 34. The ultraviolet-absorbing layer 36, which absorbs ultraviolet rays, can reduce the effect of the ultraviolet rays on the organic electroluminescent element 26. The ultraviolet-absorbing layer 36 may be formed of a conductive material so as to be in close contact with the transparent electrode 34. In this case, the transparent electrode 34 and the ultraviolet-absorbing layer 36 constitute an electrode having low electrical resistance together.

The organic electroluminescent element 26 is sealed off from moisture by a sealing film 38. The sealing film 38 on the ultraviolet-absorbing layer 36 is made of a material containing silicon nitride.

The following describes a method for manufacturing the organic electroluminescent display device according to an embodiment of the present invention with reference to FIG. 1.

In this embodiment, the substrate 10 made of, for example, glass is prepared. On the substrate 10, the undercoat 12 is formed to be a barrier against impurities from the substrate 10. The semiconductor layer 14 is formed on the undercoat 12, and the gate insulating film 20 is formed to cover the semiconductor layer 14. The gate electrode 22 is formed on the gate insulating film 20. The interlayer insulating film 24 is formed to cover the gate electrode 22.

The organic electroluminescent element 26 is formed on the interlayer insulating film 24. To that end, the lower electrode 28 is formed on the interlayer insulating film 24. The lower electrode 28 is formed of a plurality of layers. For example, the lower layer 28L is formed of a light-reflective conductive material, and the upper layer 28U is formed of a light-transmissive conductive material.

The conductive layer including a portion to be the lower electrode 28 is formed to extend through the interlayer insulating film 24 and include portions to be the source electrode 16 and the drain electrode 18 on the semiconductor layer 14. The semiconductor layer 14, the source electrode 16, the drain electrode 18, and the gate electrode 22 constitute a thin film transistor.

The insulating layer 30 is formed on the interlayer insulating film 24 and the lower electrode 28. The insulating layer 30 is formed to have an opening to part of the lower electrode 28. The insulating layer 30 is formed to be a bank enclosing the part of the lower electrode 28.

The organic layer 32 is formed on the lower electrode 28. The organic layer 32 includes at least a light-emitting layer and may further include at least one of an electron transport layer, a hole transport layer, an electron injection layer, and a hole injection layer. At least one layer constituting the organic layer 32 is made of an organic material. The organic layer 32 is formed by vapor deposition or sputtering.

The transparent electrode 34 is formed on the organic layer 32. The transparent electrode 34 is formed to lie on the insulating layer 30 to be the bank. The organic electroluminescent element 26, having the transparent electrode 34 as its top layer, is thus formed.

On the transparent electrode 34, the ultraviolet-absorbing layer 36 having a higher ultraviolet absorptivity than the transparent electrode 34 is formed. The ultraviolet-absorbing layer 36 is preferably made of a material that absorbs at least 50% of light with wavelengths of 430 nm or less. The ultraviolet-absorbing layer 36 that is formed of a conductive material so as to be in close contact with the transparent electrode 34 can constitute an electrode having low electrical resistance together with the transparent electrode 34.

The sealing film 38 is formed on the ultraviolet-absorbing layer 36 by a plasma CVD process. In the plasma CVD process, ultraviolet rays are emitted. The ultraviolet rays have wavelengths of 430 nm or less. The sealing film 38 is formed of a silicon nitride-containing material by using silane gas in the plasma CVD process.

According to this embodiment, the ultraviolet-absorbing layer 36, which absorbs ultraviolet rays, can reduce the effect of the ultraviolet rays emitted in the plasma CVD process on the organic electroluminescent element 26. Consequently, higher definition, higher brightness, greater longevity, or lower power consumption can be achieved.

An embodiment according to the present invention is expected to produce such effects, especially, for 15-inch or smaller high-definition organic EL displays with a resolution of 300 ppi or more, or for 102-inch or smaller organic EL displays with a resolution of 4K (3840×2160).

### Examples

To evaluate the effectiveness of this embodiment, the transparent electrode 34 and the ultraviolet-absorbing layer 36 were formed of various materials, the sealing film 38 was formed on them by a plasma CVD process, and then the luminescent efficiency of the organic electroluminescent element 26 was measured. Also for comparative examples in which the ultraviolet-absorbing layer 36 was not formed, the luminescent efficiency was measured.

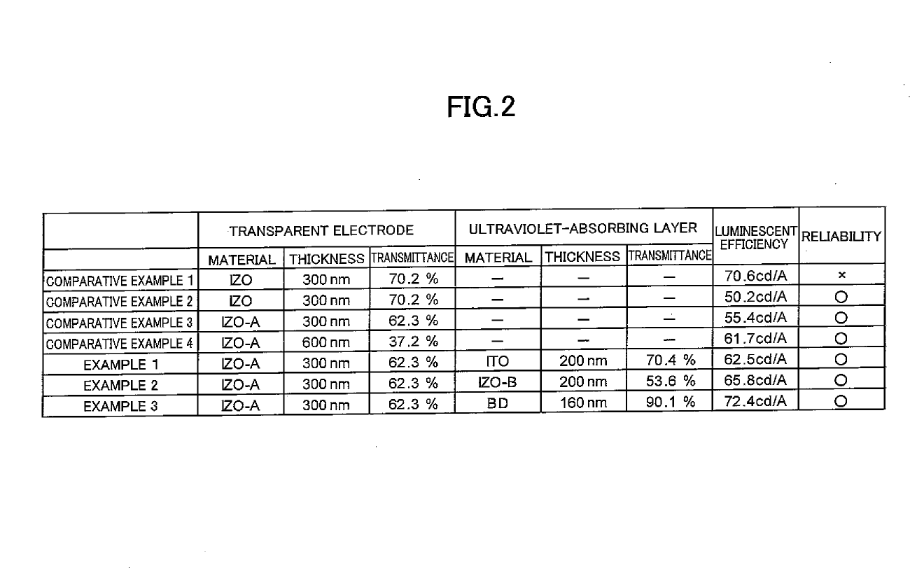

FIG. 2 is a table showing the results of an experiment to determine the effect of ultraviolet rays emitted in the plasma CVD process on the organic electroluminescent element 26. In the table, “transmittance” indicates the transmittance of ultraviolet rays with a wavelength of 420 nm, “luminescent efficiency” indicates a value measured when the organic electroluminescent element 26 was driven at a current of 10 mA/cm², and “reliability” indicates an evaluation at 80° C. at 80% relative humidity for 1000 hours.

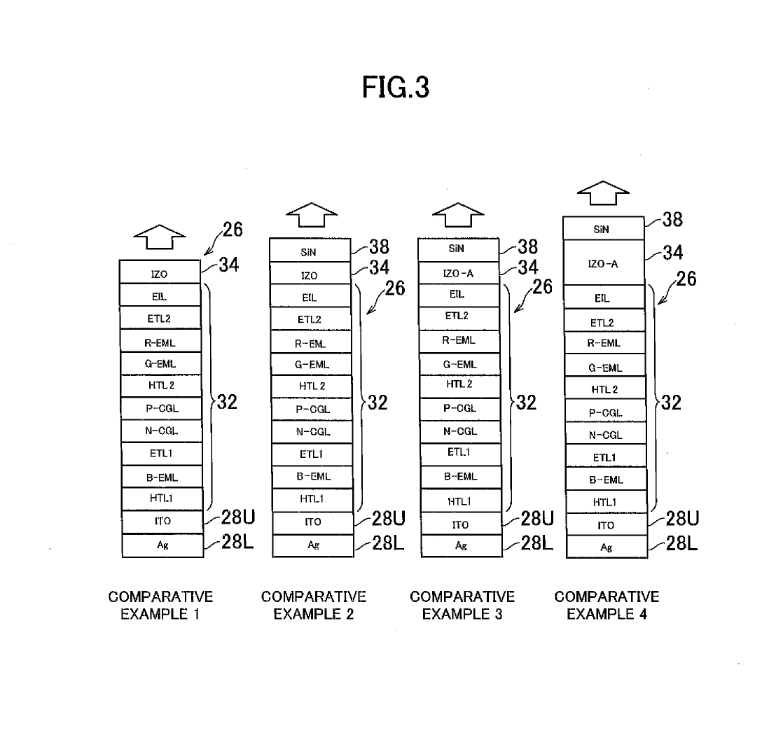

FIG. 3 is a diagram showing the organic electroluminescent elements 26 according to Comparative Examples 1 to 4. In each of Comparative Examples 1 to 4, the lower electrode 28 includes the lower layer 28L made of silver Ag, which reflects light, and the upper layer 28U formed of indium tin oxide ITO that crystallized out on the lower layer 28L. The organic layer 32 includes a first hole transport layer HTL1, a blue light-emitting layer B-EML, a first electron transport layer ETL1, an N carrier generation layer N-CGL, a P carrier generation layer P-CGL, a second hole transport layer HTL2, a green light-emitting layer G-EML, a red light-emitting layer R-EML, a second electron transport layer ETL2, and an electron injection layer EIL, which are stacked in this order from the lower electrode 28.

In Comparative Example 1, as shown in FIG. 3, the transparent electrode 34 is formed of indium zinc oxide IZO on the organic layer 32. In Comparative Example 1, the sealing film 38 is not formed. That is, no plasma CVD process is performed. Thus, no ultraviolet rays reduce the luminescent efficiency. Accordingly, as shown in FIG. 2, the luminescent efficiency is high. However, reliability in terms of resistance to moisture is not ensured.

In Comparative Example 2, as shown in FIG. 3, the sealing film 38 is formed of silicon nitride SiN. That is, the plasma CVD process is performed. The spectrum of SiH₄ plasma in the plasma CVD process has a peak light emission at a wavelength of 420 nm and a broad light emission in a wavelength range of 350 nm or less. These range of ultraviolet rays deteriorate or deactivate the light-emitting materials, and consequently reduce the luminescent efficiency. The transparent electrode 34 was formed of indium zinc oxide IZO. The oxygen flow rate of indium zinc oxide IZO during sputter deposition was 0.2 sccm. As shown in FIG. 2, the ultraviolet absorptivity of the transparent electrode 34 was 35% or less. Accordingly, in the plasma CVD process for forming the sealing film 38, the light-emitting materials were damaged and deteriorated by ultraviolet rays. The luminescent efficiency in Comparative Example 2 exhibits about a 40% drop compared with Comparative Example 1, in which no plasma CVD process is performed.

In Comparative Example 3, as shown in FIG. 3, the transparent electrode 34 was formed of indium zinc oxide IZO-A having higher ultraviolet absorptivity than indium zinc oxide IZO constituting the transparent electrode 34 of Comparative Example 2. Accordingly, as shown in FIG. 2, the light-emitting materials was less damaged than Comparative Example 2. The indium zinc oxide IZO-A was deposited by sputtering, and the oxygen flow rate during the sputter deposition was 0.3 sccm.

In Comparative Example 4, as shown in FIG. 3, the transparent electrode 34 was formed of indium zinc oxide IZO-A like the transparent electrode 34 of Comparative Example 3, but was formed thicker than the transparent electrode 34 of Comparative Example 3. This lowered the ultraviolet transmittance and reduced damage from ultraviolet rays. Thus, as shown in FIG. 2, the luminescent efficiency was better than Comparative Example 3.

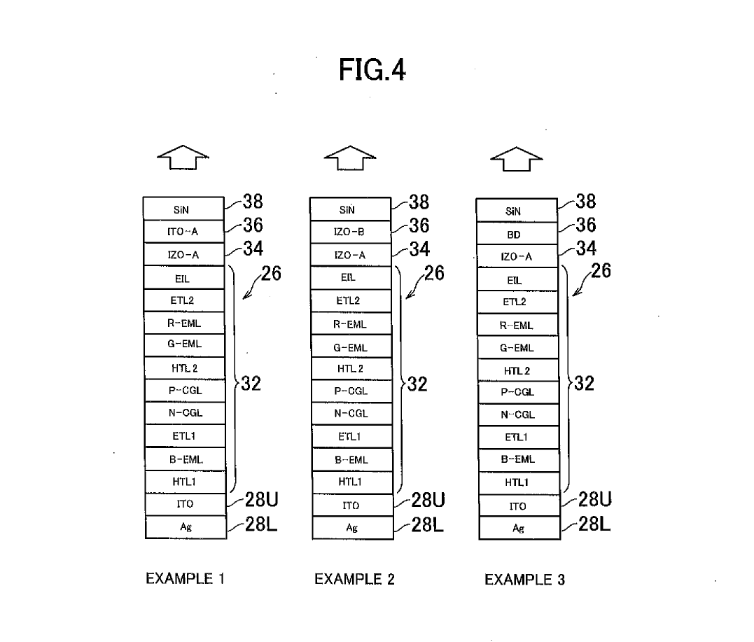

FIG. 4 is a diagram showing the organic electroluminescent elements 26 according to Examples 1 to 3. In each of Examples 1 to 3, the structure of the lower electrode 28 and the organic layer 32 is the same as that of Comparative Example 1. The sealing film 38 is also formed of silicon nitride SiN as in Comparative Examples 2 to 4.

In Example 1, as shown in FIG. 4, the transparent electrode 34 was formed of indium zinc oxide IZO-A by sputtering. The ultraviolet-absorbing layer 36 was formed of amorphous indium tin oxide ITO-A by sputtering. According to this example, as shown in FIG. 2, the ultraviolet damage was further reduced, and the luminescent efficiency was better than Comparative Example 4.

In Example 2, as shown in FIG. 4, both the transparent electrode 34 and the ultraviolet-absorbing layer 36 were formed of indium zinc oxide. However, indium zinc oxide IZO-B constituting the ultraviolet-absorbing layer 36 was formed to have a higher percentage of oxygen than indium zinc oxide IZO-A constituting the transparent electrode 34 by at least 5% or more. The indium zinc oxide IZO-B was deposited by sputtering, and the oxygen flow rate during the sputter deposition was 0.5 sccm. According to this example, as shown in FIG. 2, the ultraviolet damage was further reduced, and the luminescent efficiency was better than Example 1.

In Example 3, as shown in FIG. 4, the transparent electrode 34 was formed of indium zinc oxide IZO-A by sputtering. Then, on the transparent electrode 34, the ultraviolet-absorbing layer 36 was formed of an organic-containing material BD containing an aromatic compound or a heterocycle compound. The organic-containing material BD may contain an inorganic compound, such as transition metal, alkali metal, alkaline earth metal, or a main group element.

Examples of the aromatic compound include one or more compounds selected from the group consisting of benzene, indene, naphthalene, azulene, styrene, toluene, xylene, mesitylene, cumene, anthracene, phenanthrene, naphthacene, triphenylene, pyrene, and chrysene.

Examples of the heterocycle compound include one or more compounds selected from the group consisting of 1,4-dioxane, 1,3,5-triazine, 1,3-thiazole, 1,2-oxathiolane, 2,3-dihydroazete, 4,5-dihydro-1,3-thiazole, 3,4,5,6-tetrahydro-1,2-diazine, furan, thiophene, pyrrole, imidazole, pyran, pyridine, pyrimidine, pyrazine, pyrrolidine, piperazine, piperidine, morpholine, indole, purine, quinoline, isoquinoline, quinuclidine, chromene, thianthrene, phenothiazine, phenoxiazine, xanthene, acridine, phenazine, and carbazole.

The organic-containing material BD has a fluorescence or phosphorescence peak spectrum in a wavelength range of 440 to 470 nm and absorbs light with wavelengths of 450 nm or less. The extinction coefficient k of the organic-containing material BD was 0.05 or more in a wavelength range of 430 nm. The ultraviolet-absorbing layer 36 was formed to be 160 nm thick by depositing the organic-containing material DB.

As shown in FIG. 2, the ultraviolet-absorbing layer 36 made of the organic-containing material BD exhibited a higher ultraviolet absorptivity than the ultraviolet-absorbing layer 36 made of the indium zinc oxide IZO-B of Example 2. Accordingly, the luminescent efficiency of Example 3 is higher than that of Example 2 and approximately equal to that of Comparative Example 1, in which no silicon nitride deposition step is performed.

According to Examples 1 to 3, in a wavelength range of 420 nm or less, the ultraviolet-absorbing layer 36 having ultraviolet absorptivity was confirmed to protect the organic electroluminescent element 26 and thus achieve higher luminescent efficiency.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A method for manufacturing an organic electroluminescent display device, comprising:
forming an organic electroluminescent element having a transparent electrode as a cathode;
forming an ultraviolet-absorbing layer having a higher ultraviolet absorptivity than the transparent electrode on the transparent electrode; and
forming a sealing film on the ultraviolet-absorbing layer by a plasma CVD process.

2. The method according to claim 1, wherein
the sealing film is formed of a silicon nitride-containing material by using silane gas in the plasma CVD process.

3. The method according to claim 1, wherein
both the transparent electrode and the ultraviolet-absorbing layer are formed of indium zinc oxide, and
the ultraviolet-absorbing layer has a higher percentage of oxygen than the transparent electrode.

4. The method according to claim 1, wherein
the transparent electrode is formed of indium zinc oxide, and
the ultraviolet-absorbing layer is formed of amorphous indium tin oxide.

5. The method according to claim 1, wherein
the ultraviolet-absorbing layer is formed to contain an aromatic compound or a heterocycle compound.

6. The method according to claim 1, wherein
the ultraviolet-absorbing layer is conductive and in close contact with the transparent electrode.

7. An organic electroluminescent display device, comprising:
an organic electroluminescent element having a transparent electrode as a cathode;
an ultraviolet-absorbing layer on the transparent electrode, the ultraviolet-absorbing layer having a higher ultraviolet absorptivity than the transparent electrode; and
a sealing film on the ultraviolet-absorbing layer, the sealing film being made of a silicon nitride-containing material.

8. The organic electroluminescent display device according to claim 7, wherein
the transparent electrode is formed of indium zinc oxide, and
the ultraviolet-absorbing layer is formed of indium zinc oxide having a higher percentage of oxygen than the transparent electrode.

9. The organic electroluminescent display device according to claim 7, wherein
the transparent electrode is formed of indium zinc oxide, and
the ultraviolet-absorbing layer is formed of amorphous indium tin oxide.

10. The organic electroluminescent display device according to claim 7, wherein
the ultraviolet-absorbing layer is formed to contain an aromatic compound or a heterocycle compound.
